(19) United States
(12) Patent Application Publication
(10) Pub. No.: US 2024/0122010 A1
(43) Pub. Date: Apr. 11, 2024

(54) DISPLAY DEVICE AND ELECTRONIC DEVICE

(71) Applicant: Innolux Corporation, Miaoli County (TW)

(72) Inventors: Chandra Lius, Miaoli County (TW); Kuan-Feng Lee, Miaoli County (TW)

(73) Assignee: Innolux Corporation, Miaoli County (TW)

(21) Appl. No.: 18/462,421

(22) Filed: Sep. 7, 2023

(30) Foreign Application Priority Data
Oct. 11, 2022 (CN) 202211239023.9

(51) Int. Cl. H10K 59/131; H10K 59/35

(52) U.S. Cl. CPC H10K 59/131; H10K 59/353

(57) ABSTRACT

Disclosed is a display device including a substrate, a first light-emitting element, a first pixel circuit, a second light-emitting element, a second pixel circuit, and a first scan line. The substrate includes a functional display region and a first display region adjacent to the functional display region in a first direction. The first light-emitting element is disposed on the functional display region. The first pixel circuit is disposed on the first display region and is electrically connected to the first light-emitting element. The second light-emitting element is disposed on the first display region. The second pixel circuit is disposed on the first display region and is electrically connected to the second light-emitting element. The first scan line is electrically connected to the first pixel circuit and the second pixel circuit and extends in a second direction perpendicular to the first direction. An electronic device is also disclosed.

### CROSS-REFERENCE TO RELATED APPLICATION

This application claims the priority benefit of Chinese application no. 202211239023.9, filed on Oct. 11, 2022. The entirety of the above-mentioned patent application is hereby incorporated by reference herein and made a part of this specification.

### BACKGROUND

### Technical Field

The disclosure relates to a display device and an electronic device.

### Description of Related Art

Compared with digging holes on a display panel to accommodate a sensing module, disposing the sensing module under a functional display region of the display panel can effectively reduce the border or help increase the size of the display region. However, opaque elements (e.g., driving elements and/or metal wirings) located in the functional display region may reduce the transparency of this region and affect sensing results of the sensing module.

### SUMMARY

The disclosure provides a display device that helps improve transparency of a functional display region.

According to an embodiment of the disclosure, a display device includes a substrate, a first light-emitting element, a first pixel circuit, a second light-emitting element, a second pixel circuit, and a first scan line. The substrate includes a functional display region and a first display region adjacent to the functional display region in a first direction. The first light-emitting element is disposed on the functional display region. The first pixel circuit is disposed on the first display region and is electrically connected to the first light-emitting element. The second light-emitting element is disposed on the first display region. The second pixel circuit is disposed on the first display region and is electrically connected to the second light-emitting element. The first scan line is electrically connected to the first pixel circuit and the second pixel circuit and extends in a second direction perpendicular to the first direction.

According to an embodiment of the disclosure, an electronic device includes the display device and a sensing device. The sensing device overlaps the functional display region in a top view of the display device.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A, FIG. 2, FIG. 3, FIG. 4A, FIG. 5A, FIG. 6A, FIG. 7 to FIG. 10, FIG. 11B, and FIG. 12 are respectively schematic top views of display devices according to various embodiments of the disclosure.

FIG. 1B, FIG. 4B, FIG. 5B, and FIG. 6B are respectively schematic sectional views of section line I-I′ in FIG. 1A, section line II-II′ in FIG. 4A, section line III-III′ in FIG. 5A, and section line IV-IV′ in FIG. 6A.

FIG. 11A is a schematic perspective view of a display device according to an embodiment of the disclosure.

FIG. 11C is a schematic partially enlarged view of a functional display region, a buffer region, and a first-side display region in FIG. 11B.

### DESCRIPTION OF THE EMBODIMENTS

Reference will now be made in detail to the exemplary embodiments of the disclosure, examples of which are illustrated in the accompanying drawings. Wherever possible, the same reference numerals are used in the drawings and description to refer to the same or like parts.

Some terms are used to refer to specific elements throughout the description and the appended claims of the disclosure. A person skilled in the art should understand that an electronic device manufacturer may use different names to refer to the same elements. The disclosure is not intended to distinguish elements that have the same functions but different names. In the description and the claims hereinafter, terms such as “include”, “comprise”, and “have’ are open-ended terms, and should thus be interpreted as “including, but not limited to”.

The directional terms mentioned herein, like “above”, “below”, “front”, “rear, “left”, “right”, and the like, refer only to the directions in the accompanying drawings. Therefore, the directional terms are used for describing instead of limiting the disclosure. Each of the drawings illustrate typical features of methods, structures, and/or materials used in specific embodiments. Nonetheless, the drawings should not be interpreted as defining or limiting ranges or properties encompassed by these embodiments. For example, the relative sizes, thicknesses, and positions of film layers, regions, and/or structures may be reduced or enlarged for clarity.

In the disclosure, when a structure (or layer, element, substrate) is described as being located on/above another structure (or layer, element, substrate), it may refer to the case that the two structures are adjacent and directly connected, or the two structures are adjacent but not directly connected. Non-direct connection refers to the case that at least one intermediary structure (or intermediary layer, intermediary element, intermediary substrate, intermediary spacing) is present between the two structures, where a lower side surface of one structure is adjacent to or directly connected to an upper side surface of the intermediary structure, and an upper side surface of the other structure is adjacent to or directly connected to a lower side surface of the intermediary structure. The intermediary structure may be composed of a single-layer or multi-layer physical structure or non-physical structure with no limitation. In the disclosure, when a structure is disposed “on” another structure, it is possible that the structure is “directly” on the another structure, or the structure is “indirectly” on the another structure, namely at least one structure is further sandwiched between the structure and the another structure.

The terms “about”, “equal”, “equivalent”, “same”, “substantially”, or “essentially” are generally interpreted as that a value is within 20% of a given value or range, or within 10%, 5%, 3%, 2%, 1%, or 0.5% of a given value or range. In addition, the description “the range is from a first value to a second value” or “the range falls within a range of a first value to a second value” indicates that the range includes the first value, the second value, and other values in between.

In the description and the claims, the use of an ordinal number such as “first”, “second”, and so on to modify an element does not by itself connote or represent any preceding ordinal number of the element(s); any priority, precedence, or order of one element over another; or the order in which a manufacturing method is performed, but only to clearly distinguish an element having a certain name from another element having the same name. The same terms may be not used in the claims as used in the description, and accordingly a first member in the description may be a second member in the claims.

The term electrically connection or coupling described in the disclosure refers to direct or indirect connection. In the case of direct connection, end points of elements on two circuits are directly connected or interconnected by a conductor line segment. In the case of indirect connection, present between end points of elements on two circuits is a switch, a diode, a capacitor, an inductor, other suitable elements, or a combination of the above elements, but not limited thereto.

In the disclosure, a thickness, a length, and a width may be measured using an optical microscope (OM), and the thickness or width may be measured from a cross-sectional image shown in an electron microscope, but not limited thereto. In addition, certain errors may exist between any two values or directions for comparison. If a first value is equal to a second value, it implies that there may be an error of about 10% between the first value and the second value. If a first direction is perpendicular to a second direction, the angle between the first direction and the second direction may be between 80 degrees and 100 degrees. If a first direction is parallel to a second direction, the angle between the first direction and the second direction may be between 0 degree and 10 degrees. Furthermore, the terms “equal”, “equivalent”, “same”, “substantially”, or “essentially” mentioned herein typically represents that a value is within 10% of a given value or range. Moreover, the description “a given range is from a first value to a second value” or “a given range falls within a range of a first value to a second value” indicates that the given range includes the first value, the second value, and other values in between. If a first direction is perpendicular to a second direction, the angle between the first direction and the second direction may be between 80 degrees and 100 degrees. If a first direction is parallel to a second direction, the angle between the first direction and the second direction may be between 0 degree and 10 degrees.

Unless otherwise defined, all terms (including technical and scientific terms) used herein have the same meaning as commonly understood by one of ordinary skill in the art related to the disclosure. It will be understood that terms, such as those defined in commonly used dictionaries, should be interpreted as having a meaning that is consistent with their meaning in the background or the context of the relevant art and the disclosure and will not be interpreted in an idealized or overly formal sense unless particularly so defined in the embodiments of the disclosure.

In the disclosure, an electronic device may include a display device, a backlight device, an antenna device, a sensing device, or a tiled device, but not limited thereto. The electronic device may be a bendable or flexible electronic device. The electronic device may be a non-self-luminous-mode display device or a self-luminous-mode display device. The electronic device may include, for example but not limited to, a liquid crystal, a light-emitting diode (LED), fluorescence, phosphor, a quantum dot (QD), other suitable display media, or a combination thereof. The antenna device may be in a liquid crystal form or in a non-liquid crystal form, and the sensing device may sense capacitance, light rays, thermal energy, or ultrasonic waves, but not limited thereto. In the disclosure, the electronic device may include electronic components, and the electronic components may include passive components or active components, such as a capacitor, resistor, inductor, diode, transistor, or the like. The diode may include an LED or a photodiode. The LED may include, for example but not limited to, an organic light-emitting diode (OLED), a mini LED, a micro LED, or a quantum dot (QD) LED (e.g., QLED or QDLED). The tiled display device may be a tiled display device or a tiled antenna device, for example but not limited thereto. It should be noted that the electronic device may be any arrangement or combination of the above, but is not limited thereto. In addition, the electronic device may have a shape of a rectangle, a circle, or a polygon, a shape with curved edges, or other suitable shapes. The electronic device may have peripheral systems such as a driving system, a control system, a light source system, or the like to support a display device, an antenna device, a wearable device (including augmented reality or virtual reality, for example), vehicle mounted device (including an automotive windshield, for example), or a tiled device.

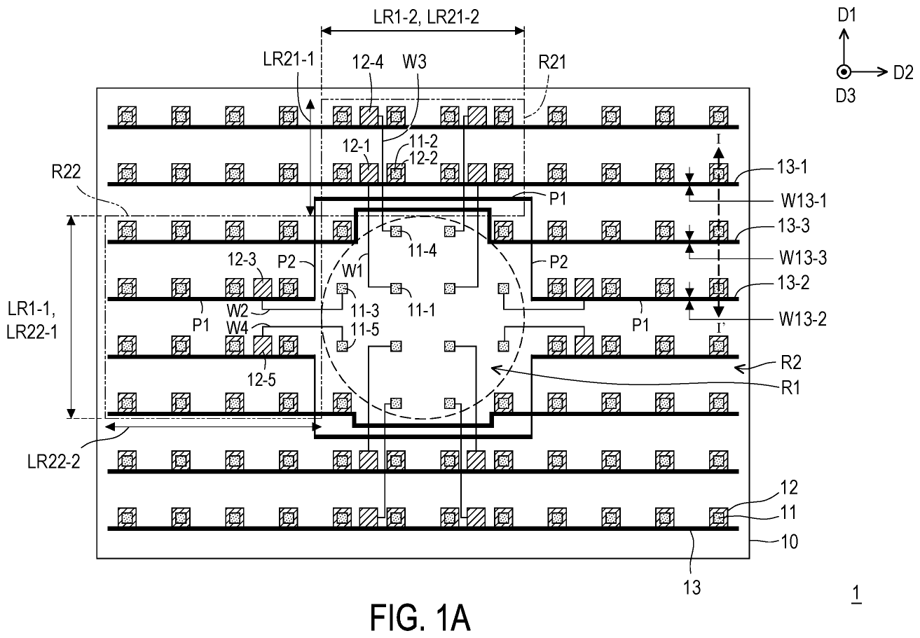

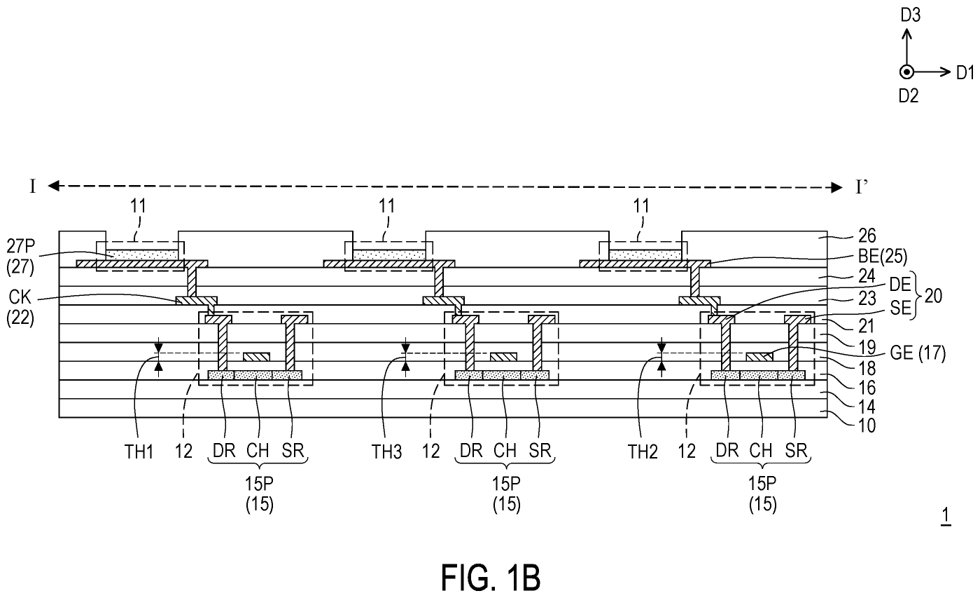

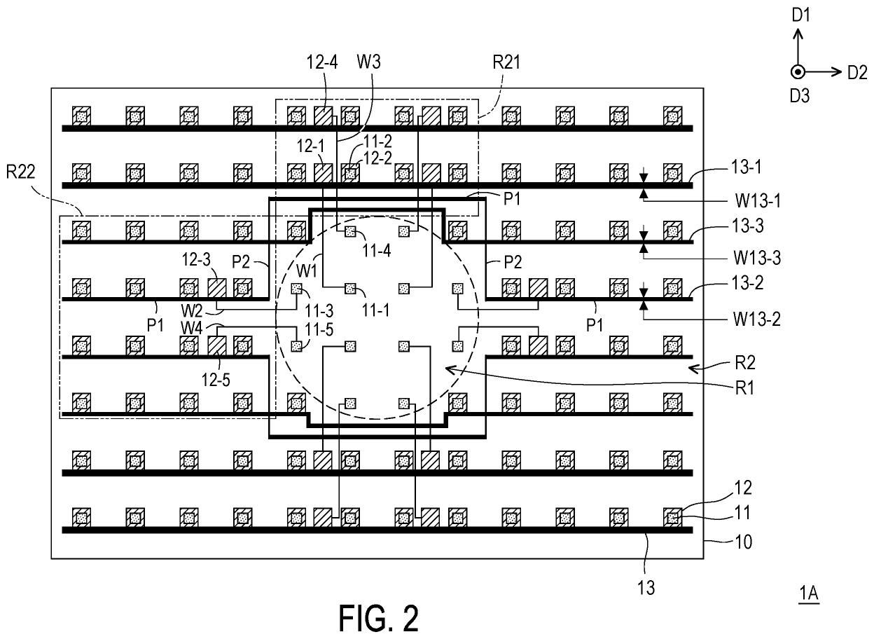

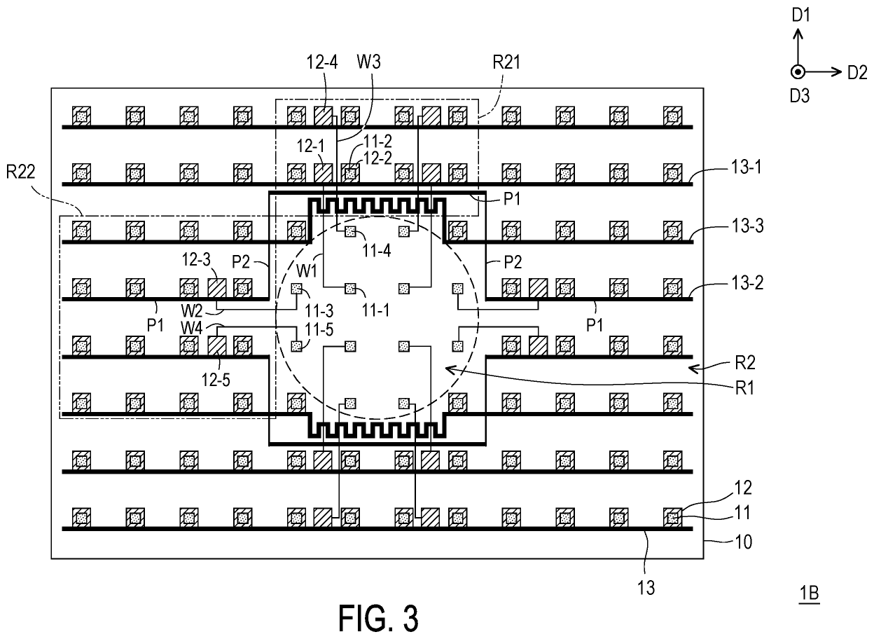

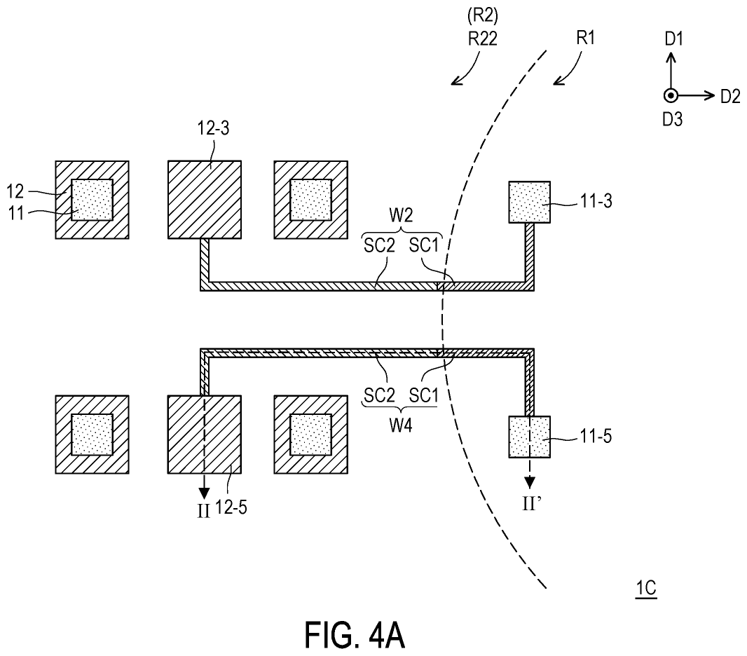

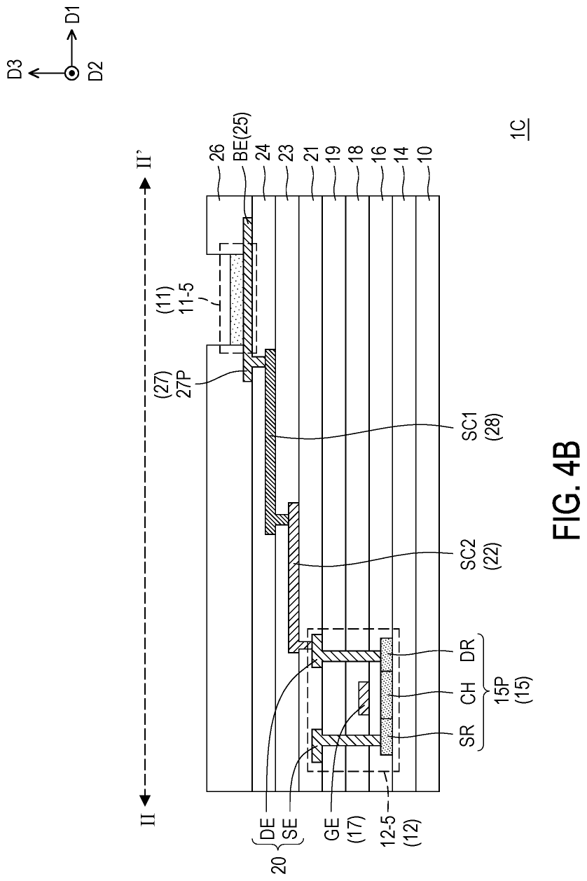

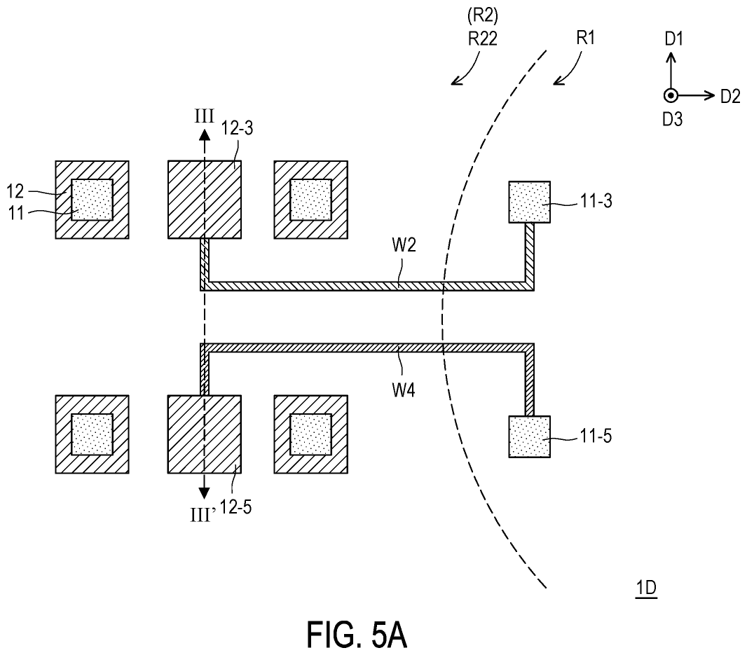

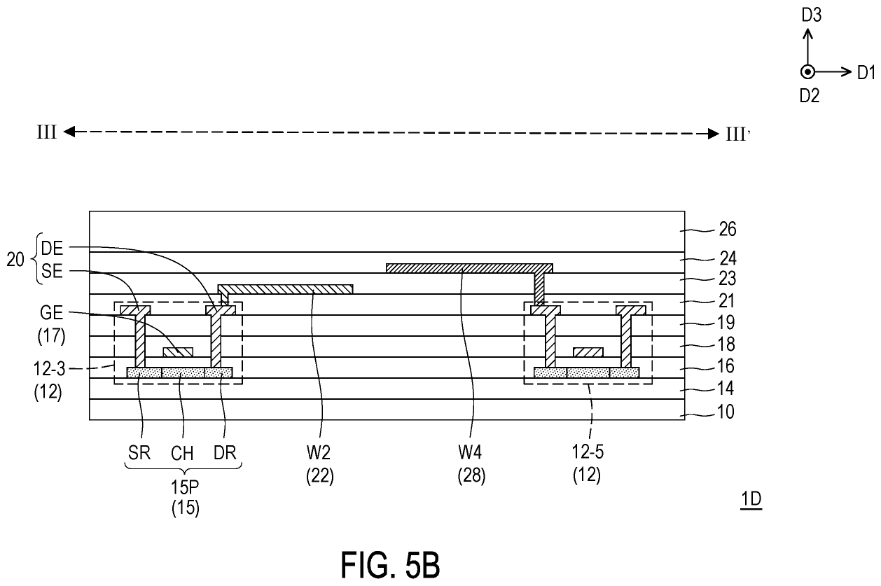

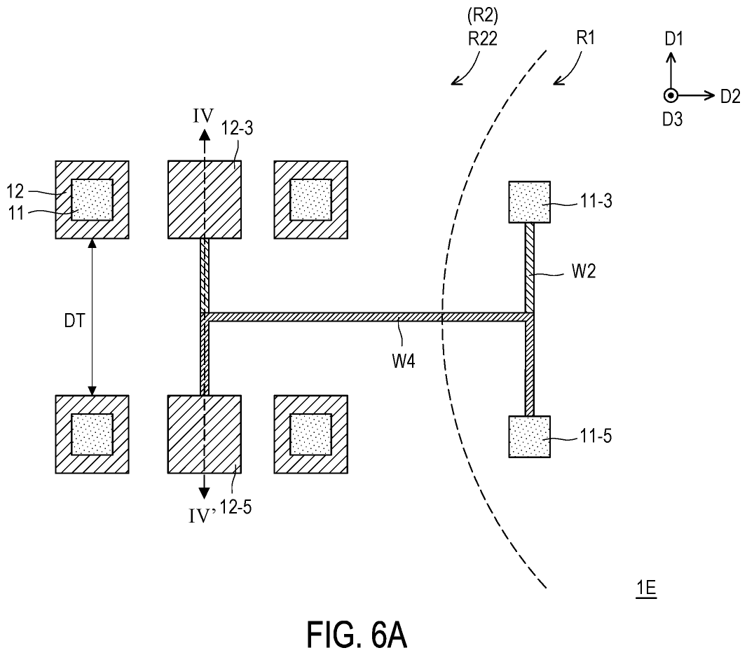

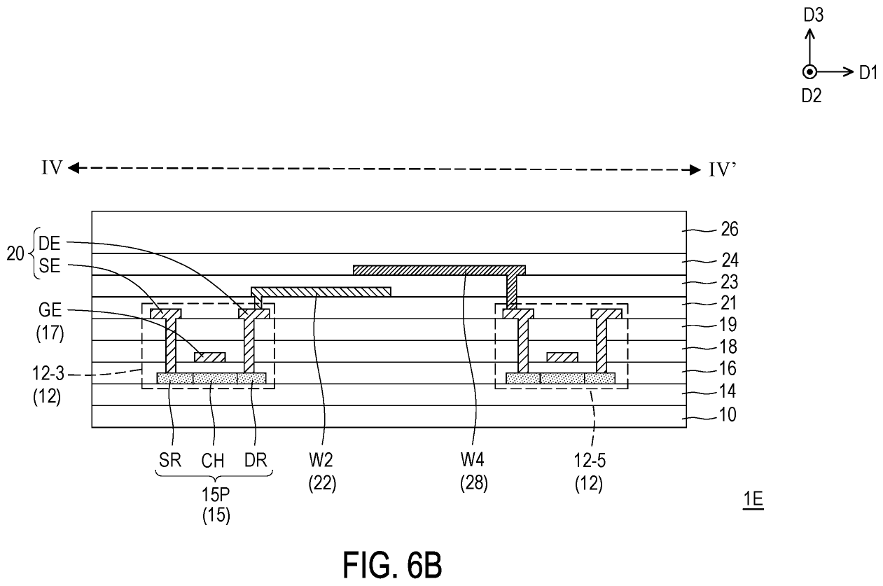

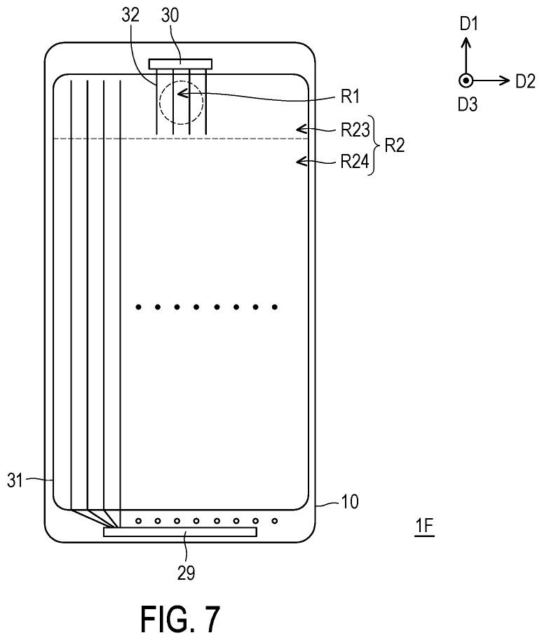

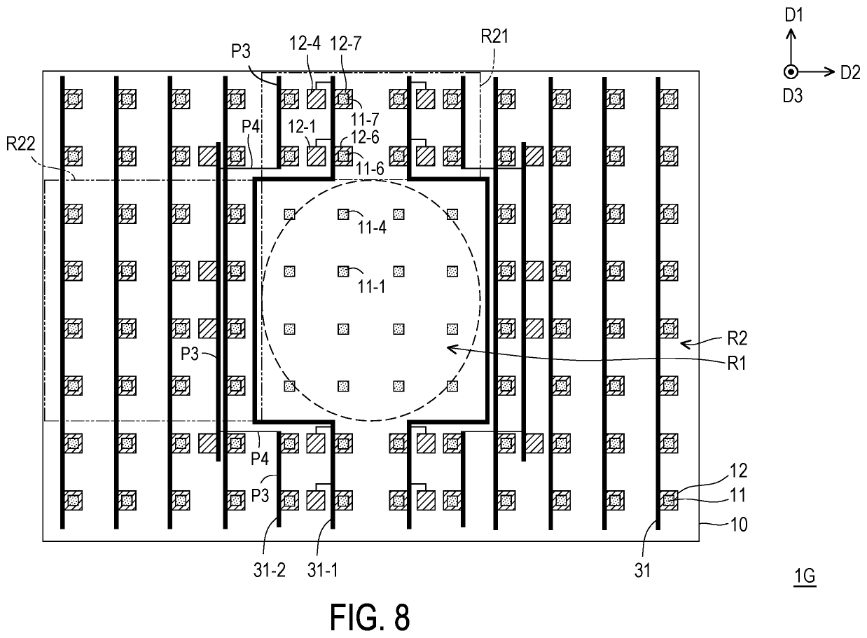

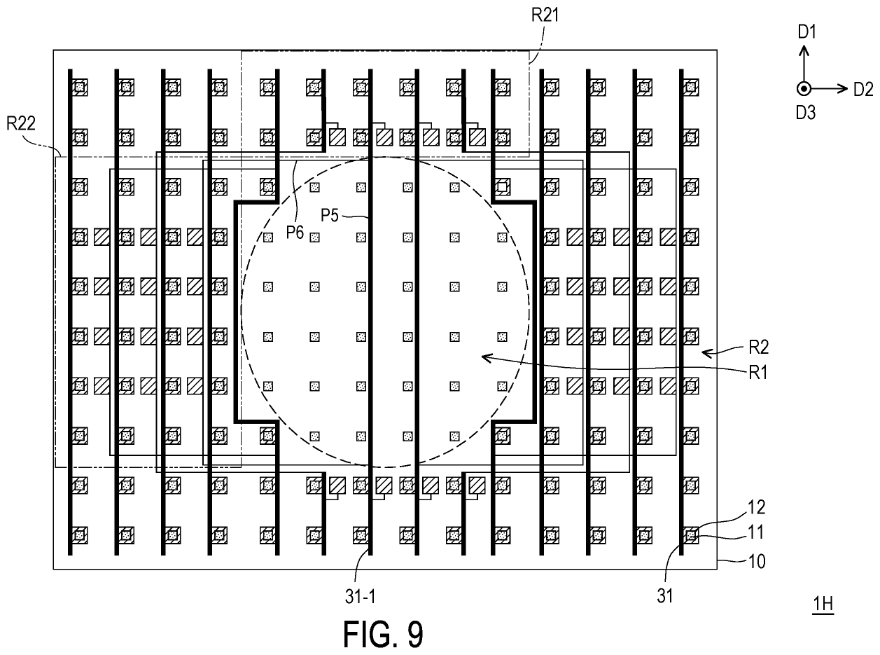

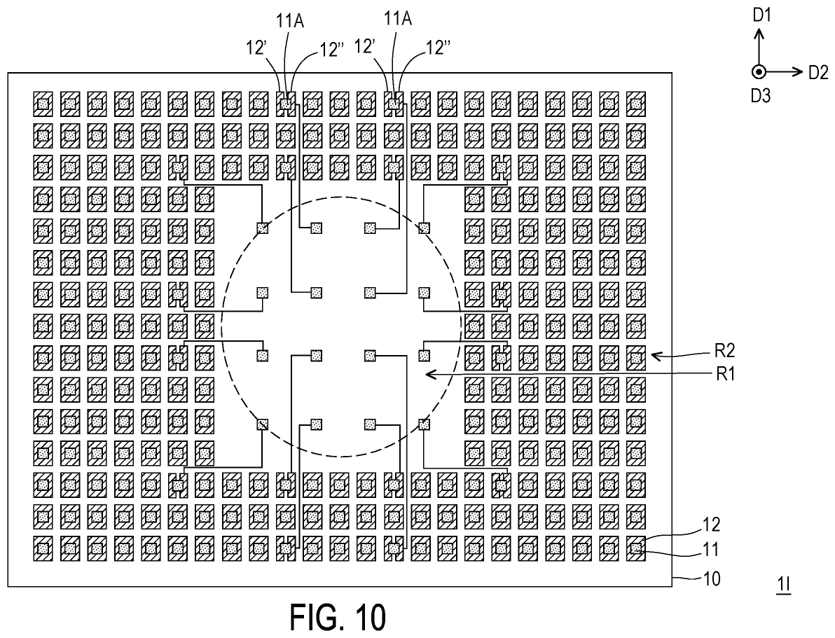

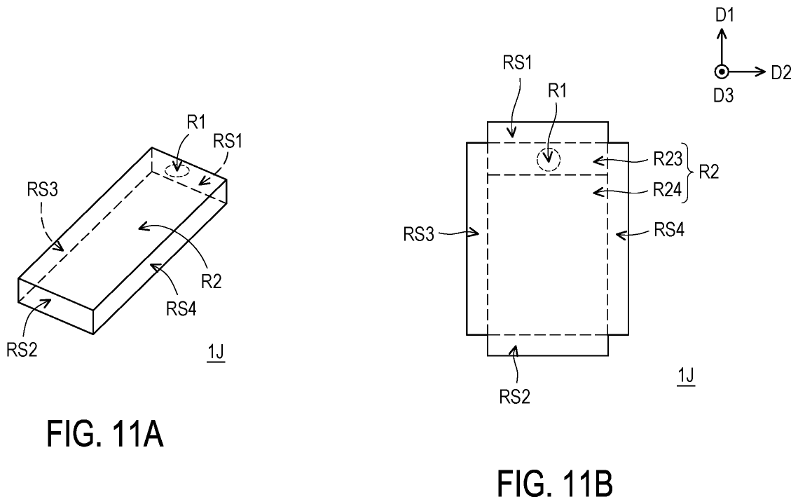

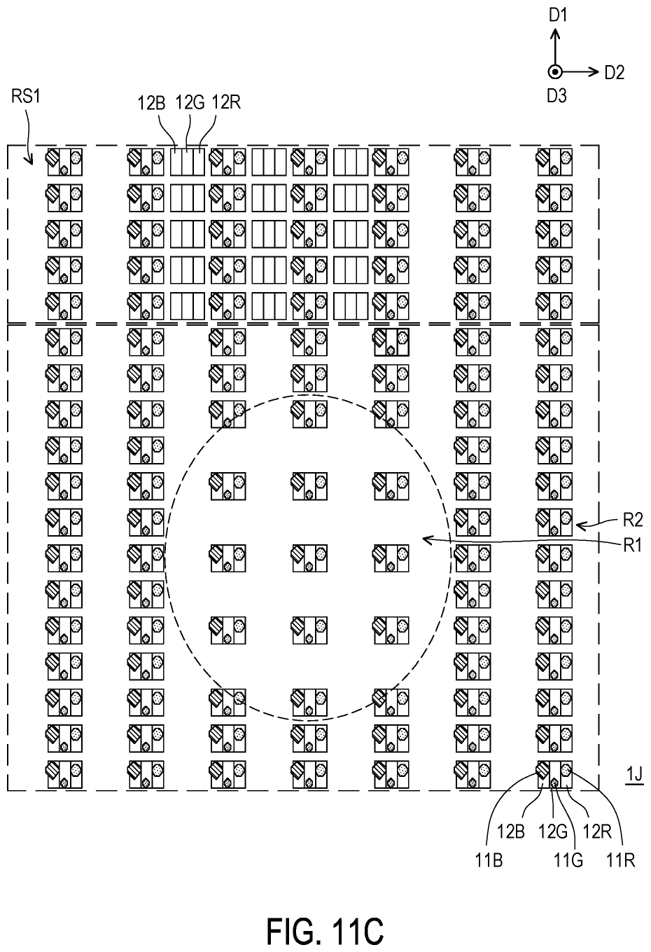

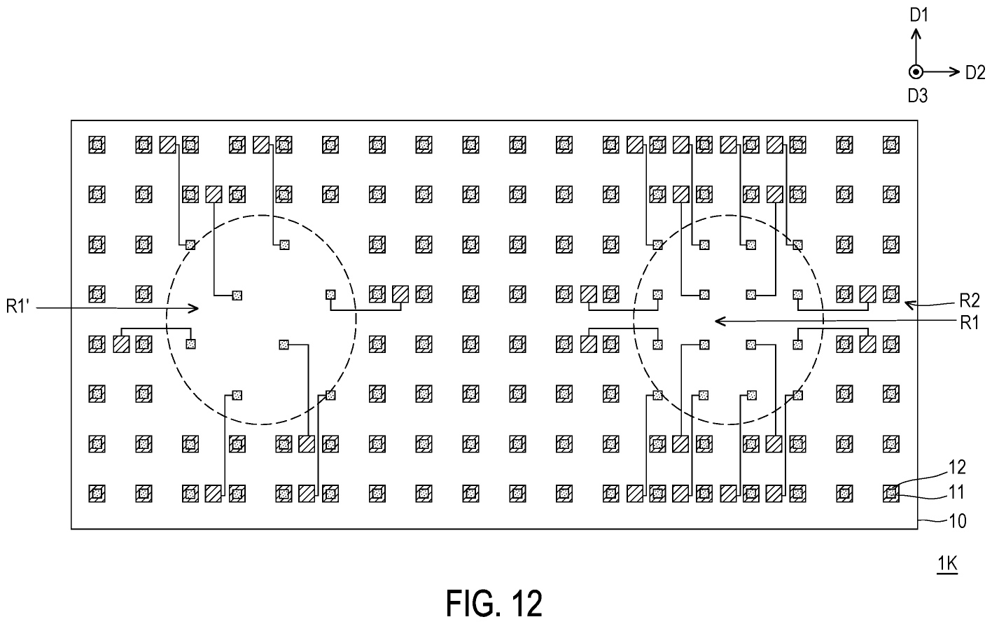

FIG. 1A, FIG. 2, FIG. 3, FIG. 4A, FIG. 5A, FIG. 6A, FIG. 7 to FIG. 10, FIG. 11B, and FIG. 12 are respectively schematic top views of display devices according to various embodiments of the disclosure. FIG. 1B, FIG. 4B, FIG. 5B, and FIG. 6B are respectively schematic sectional views of section line I-I′ in FIG. 1A, section line II-II′ in FIG. 4A, section line III-III′ in FIG. 5A, and section line IV-IV′ in FIG. 6A. FIG. 11A is a schematic perspective view of a display device according to an embodiment of the disclosure. FIG. 11C is a schematic partially enlarged view of a functional display region, a buffer region, and a first-side display region in FIG. 11B. Technical solutions provided in FIG. 1A to FIG. 12 may be used in replacement, combination, or mixture with each other to form another embodiment without departing from the spirit of the disclosure.

With reference to FIG. 1A, a display device 1 may include a substrate 10, a plurality of light-emitting elements 11, a plurality of pixel circuits 12, and a plurality of scan lines 13, but not limited thereto. Although not shown in FIG. 1A for clarity of the drawing, the display device 1 may also include a plurality of data lines and at least one insulating layer. The data lines and the scan lines 13 intersect each other and may be electrically insulated from each other by the at least one insulating layer. For details of the data lines, reference may be made to the relevant description of FIG. 7 to FIG. 9, which will not be repeated here.

To be specific, the substrate 10 may be a rigid substrate or a flexible substrate. The material of the substrate 10 includes, for example, glass, quartz, ceramic, sapphire, or plastic, but not limited thereto. The plastic may include polycarbonate (PC), polyimide (PI), polypropylene (PP), polyethylene terephthalate (PET), other suitable flexible materials, or a combination thereof, but not limited thereto. In addition, the light transmittance of the substrate 10 is not limited. In other words, the substrate 10 may be a light-transmitting substrate, a semi-transparent substrate, or an opaque substrate.

The substrate 10 may include a functional display region R1 and a general display region R2. For the convenience in identification, FIG. 1A shows the boundary between the functional display region R1 and the general display region R2 with a broken-line frame, where the functional display region R1 is inside the broken-line frame, and the general display region R2 is outside the broken-line frame. Although the broken-line frame is shown as a circle, it should be understood that the shape of the boundary between the two regions may also be a rectangle or other polygons.

In addition to providing a display function, the functional display region R1 may also provide additional functions. For example, in applications of the display device 1 to an electronic device (not shown), a sensing device (which is not shown, and is a camera module, for example) in the electronic device may be disposed below the functional display region R1 (i.e., the sensing device overlaps the functional display region R1 in a top view of the display device 1) to provide functions, for example but not limited to, image capturing, video capturing, or biometric identification (e.g., fingerprint identification). The general display region R2 is outside the functional display region R1 and provides a display function.

The light-emitting elements 11 are disposed on the functional display region R1 and the general display region R2 and are arranged into an array in a first direction D1 and a second direction D2 perpendicular to the first direction D1. According to some embodiments, as shown in FIG. 1A, the light-emitting elements 11 on the functional display region R1 may be equal to the light-emitting elements 11 on the general display region R2 in distribution density, to improve the display quality of the functional display region R1. According to other embodiments, although not shown in FIG. 1A, the light-emitting elements 11 on the functional display region R1 may be less than the light-emitting elements 11 on the general display region R2 in distribution density, to improve the transparency of the functional display region R1.

The light-emitting elements 11 may include a plurality of LEDs, a plurality of OLEDs, a plurality of mini LEDs, a plurality of micro LEDs, or a plurality of QDLEDs. Depending on different requirements, the light-emitting elements 11 may include a plurality of light-emitting elements of different colors or a plurality of light-emitting elements of a single color. For example, when the light-emitting elements 11 serve as display pixels, the light-emitting elements 11 may include a plurality of red light-emitting elements, a plurality of green light-emitting elements, and a plurality of blue light-emitting elements, but not limited thereto. Comparatively, when the light-emitting elements 11 serve as backlights, the light-emitting elements 11 may include a plurality of monochromatic light-emitting elements, for example but not limited to, a plurality of white light-emitting elements or a plurality of blue light-emitting elements.

The pixel circuits 12 may be respectively electrically connected to the light-emitting elements 11. Each pixel circuit 12 includes a plurality of active elements, for example but not limited to, a plurality of thin film transistors. According to some embodiments, as shown in FIG. 1A, the pixel circuits 12 and the light-emitting elements 11 are in the same number and are disposed in one-to-one correspondence. Moreover, the pixel circuits 12 are disposed on the general display region R2 and do not overlap the functional display region R1 in a third direction D3 perpendicular to the first direction D1 and the second direction D2, to improve the transparency of the functional display region R1. Nonetheless, the disclosure is not limited thereto. According to other embodiments, although not shown in FIG. 1A, the display device 1 may also include other pixel circuits being also electrically connected to the light-emitting elements 11. One of the pixel circuits includes a plurality of active elements, of which some are disposed on the functional display region R1 and some other are disposed on the general display region R2. For example, the active elements disposed on the functional display region R1 are emission control transistors, and the active elements disposed on the general display region R2 are driving transistors. Disposing at least some of the active elements outside the functional display region R1 helps improve the transparency of the functional display region R1.

The pixel circuits 12 electrically connected to the light-emitting elements 11 disposed on the general display region R2 may overlap the corresponding light-emitting elements 11 in the third direction D3, but not limited thereto. The pixel circuits 12 electrically connected to the light-emitting elements 11 disposed on the functional display region R1 may be located outside the functional display region R1 and disposed adjacent to the functional display region R1. For example, the pixel circuits 12 may be distributed around the functional display region R1 and each located between two adjacent light-emitting elements 11 in the second direction D2, but not limited thereto.

According to some embodiments, the pixel circuits 12 electrically connected to a plurality of (e.g., two or four) light-emitting elements 11 arranged on the functional display region R1 along the first direction D1 may be arranged on a longitudinal line extending along the first direction D1. Comparatively, the pixel circuits 12 electrically connected to a plurality of (e.g., two or four) light-emitting elements 11 arranged on the functional display region R1 along the second direction D2 may be arranged on one or more horizontal lines (e.g., the scan lines 13) extending along the second direction D2 and share one or more scan lines 13 with the corresponding pixel circuits 12 on the general display region R2.

For the convenience in description, the general display region R2 is further divided into a first display region R21 (see the broken-line frame at the above side) and a second display region R22 (see the broken-line frame at the left side). The first display region R21 is adjacent to the functional display region R1 in the first direction D1, and the second display region R22 is adjacent to the functional display region R1 in the second direction D2. For example, the shape of each of the first display region R21 and the second display region R22 is a rectangle. A length LR21-2 of the first display region R21 in the second direction D2 is equal to a length LR1-2 of the functional display region R1 in the second direction D2, and a length LR21-1 of the first display region R21 in the first direction D1 is a distance of 1 to M pixel pitches, where M depends on the number of pixel pitches by which the uppermost pixel is distant from the functional display region R1. In FIG. 1A, M is 2, for example. A length LR22-1 of the second display region R22 in the first direction D1 is equal to a length LR1-1 of the functional display region R1 in the first direction D1, and a length LR22-2 of the second display region R22 in the second direction D2 is a distance of 1 to N pixel pitches, where N depends on the number of pixel pitches by which the leftmost pixel is distant from the functional display region R1. In FIG. 1A, N is 4, for example.

According to some embodiments, two pixel circuits 12 electrically connected to two light-emitting elements 11 respectively disposed on the functional display region R1 and the first display region R21 and arranged in the first direction D1 may share one scan line 13. Taking FIG. 1A as an example, a first light-emitting element 11-1 among the light-emitting elements 11 is disposed on the functional display region R1. A first pixel circuit 12-1 among the pixel circuits 12 is disposed on the first display region R21 and is electrically connected to the first light-emitting element 11-1. The first pixel circuit 12-1 may be electrically connected to the first light-emitting element 11-1 through a first line W1, for example but not limited thereto. A second light-emitting element 11-2 among the light-emitting elements 11 is disposed on the first display region R21, and the second light-emitting element 11-2 and the first light-emitting element 11-1 are arranged in the first direction D1, for example. A second pixel circuit 12-2 among the pixel circuits 12 is disposed on the first display region R21 and is electrically connected to the second light-emitting element 11-2. The second pixel circuit 12-2 may be electrically connected to the second light-emitting element 11-2 through a circuit CK (not shown in FIG. 1A; see FIG. 1B), for example but not limited thereto. The second pixel circuit 12-2 and the second light-emitting element 11-2 are disposed overlapping in the third direction D3, for example but not limited thereto. The first pixel circuit 12-1 and the second pixel circuit 12-2 are arranged in the second direction D2, for example. A first scan line 13-1 among the scan lines 13 is electrically connected to the first pixel circuit 12-1 and the second pixel circuit 12-2 and extends in the second direction D2.

According to some embodiments, two pixel circuits 12 electrically connected to two light-emitting elements 11 disposed on the functional display region R1 and arranged in the second direction D2 may be electrically connected to different scan lines 13. Taking FIG. 1A as an example, a third light-emitting element 11-3 among the light-emitting elements 11 is disposed on the functional display region R1, and the third light-emitting element 11-3 and the first light-emitting element 11-1 are arranged in the second direction D2, for example. A third pixel circuit 12-3 among the pixel circuits 12 is disposed on the second display region R22 and is electrically connected to the third light-emitting element 11-3. The third pixel circuit 12-3 may be electrically connected to the third light-emitting element 11-3 through a second line W2, for example but not limited thereto. For example, the first line W1 extends in the first direction D1 and electrically connects the first light-emitting element 11-1 with the first pixel circuit 12-1. For example, the second line W2 extends in the second direction D2 and electrically connects the third light-emitting element 11-3 with the third pixel circuit 12-3. In the disclosure, the extension direction of the portion of the line that accounts for 70% or above of the total length of the line is defined as the extension direction of the line. In other words, the portion of the first line W1 that accounts for 70% or above of the total length of the first line W1 extends in the first direction D1, and the portion of the second line W2 that accounts for 70% or above of the total length of the second line W2 extends in the second direction D2. A second scan line 13-2 among the scan lines 13 is electrically connected to the third pixel circuit 12-3. In other words, the first pixel circuit 12-1 and the third pixel circuit 12-3 are electrically connected to different scan lines 13 (e.g., the first scan line 13-1 and the second scan line 13-2).

According to some embodiments, two pixel circuits 12 electrically connected to two light-emitting elements 11 disposed on the functional display region R1 and arranged in the first direction D1 may be arranged on the first display region R21 along the first direction D1. Taking FIG. 1A as an example, a fourth light-emitting element 11-4 among the light-emitting elements 11 is disposed on the functional display region R1, and the fourth light-emitting element 11-4 and the first light-emitting element 11-1 are arranged in the first direction D1, for example. A fourth pixel circuit 12-4 among the pixel circuits 12 is disposed on the first display region R21 and is electrically connected to the fourth light-emitting element 11-4. The fourth pixel circuit 12-4 may be electrically connected to the fourth light-emitting element 11-4 through a third line W3, for example but not limited thereto. For example, the third line W3 extends in the first direction D1, and the fourth pixel circuit 12-4 and the first pixel circuit 12-1 may be arranged on the first display region R21 along the first direction D1.

According to some embodiments, two pixel circuits 12 electrically connected to two light-emitting elements 11 disposed on the functional display region R1 and arranged in the first direction D1 may be arranged on the second display region R22 along the first direction D1. Taking FIG. 1A as an example, a fifth light-emitting element 11-5 among the light-emitting elements 11 is disposed on the functional display region R1, and the fifth light-emitting element 11-5 and the third light-emitting element 11-3 are arranged in the first direction D1, for example. A fifth pixel circuit 12-5 among the pixel circuits 12 is disposed on the second display region R22 and is electrically connected to the fifth light-emitting element 11-5. The fifth pixel circuit 12-5 may be electrically connected to the fifth light-emitting element 11-5 through a fourth line W4, for example but not limited thereto. For example, the fourth line W4 extends in the second direction D2, and the fifth pixel circuit 12-5 and the third pixel circuit 12-3 may be arranged on the second display region R22 along the first direction D1.

According to some embodiments, different scan lines 13 may be electrically connected to different numbers of pixel circuits 12. Under this architecture, resistive-capacitive (RC) loadings of different scan lines 13 may approach the same loading through the design of parameters (e.g., a thickness, a width, or a length) of the scan lines 13. For example, as the number of pixel circuits 12 electrically connected to the scan line 13 increases, the scan line 13 may be designed to have an increasing thickness, an increasing width, and/or a decreasing length. In the disclosure, the thickness of the scan line 13 may be measured at half of the bottom width in the cross-sectional view of the scan line 13; and the width of the scan line 13 may be the bottom width in the cross-sectional view of the scan line 13.

Taking FIG. 1A as an example, the number (e.g., 14) of pixel circuits 12 electrically connected to the first scan line 13-1 is greater than the number (e.g., 10) of pixel circuits 12 electrically connected to the second scan line 13-2, and the number of pixel circuits 12 electrically connected to the second scan line 13-2 is equal to the number of pixel circuits 12 electrically connected to a third scan line 13-3. Under this architecture, as shown in FIG. 1B, a thickness (e.g., a thickness TH1) of the first scan line 13-1 may be designed to be greater than a thickness (e.g., a thickness TH2) of the second scan line 13-2, and the thickness (e.g., the thickness TH2) of the second scan line 13-2 may be designed to be equal to a thickness (e.g., a thickness TH3) of the third scan line 13-3. The relationship between the relative thicknesses of the remaining scan lines 13 may be deduced by analogy, and will not be repeatedly described below.

In other embodiments, although not shown in FIG. 1A or FIG. 1B, a width W13-1 of the first scan line 13-1 may be designed to be greater than a width W13-2 of the second scan line 13-2, and the width W13-2 of the second scan line 13-2 may be designed to be equal to a width W13-3 of the third scan line 13-3. In other embodiments, the first scan line 13-1 may be designed to be less than the second scan line 13-2 in length, and the second scan line 13-2 may be designed to be equal or similar to the third scan line 13-3 in length. The lengths of the second scan line 13-2 and the third scan line 13-3 may be increased through the design of an adapter cable, a winding, or a combination thereof, for example but not limited thereto. In other embodiments, the RC loadings of different scan lines 13 may be controlled by modulating at least two of the thickness, width, and length parameters of the scan lines 13.

In FIG. 1A, the second scan line 13-2 adopts an adapter cable design to increase the length of the second scan line 13-2 or reduce the shielding of the second scan line 13-2 to the functional display region R1. To be specific, the second scan line 13-2 includes three first portions P1 (represented by thick solid lines) and two second portions P2 (represented by thin solid lines). The three first portions P1 each extend in the second direction D2, and the two second portions P2 each extend in the first direction D1. From the top view of the display device 1, the three first portions P1 are respectively disposed at the left, right, and upper side of the functional display region R1, and the two second portions P2 are respectively disposed at the left and right sides of the functional display region R1. The second portion P2 located at the left side of the functional display region R1 electrically connects the first portion P1 located at the left side of the functional display region R1 with the first portion P1 located at the upper side of the functional display region R1, and the second portion P2 located at the right side of the functional display region R1 electrically connects the first portion P1 located at the right side of the functional display region R1 with the first portion P1 located at the upper side of the functional display region R1. A conductive layer (e.g., a conductive layer 17 in FIG. 1B) to which the three first portions P1 belong is different from a conductive layer (which is not shown, and is located between a dielectric layer 18 and a dielectric layer 19 in FIG. 1B, for example) to which the two second portions P2 belong. The second portions P2 are electrically connected to the corresponding first portions P1 through conductive vias (not shown) penetrating the dielectric layer 18, for example.

In FIG. 1A, the third scan line 13-3 adopts a winding design. In other words, the third scan line 13-3 changes the extension direction of the line under the architecture of the same conductive layer (e.g., the conductive layer 17 in FIG. 1B) to increase the length of the third scan line 13-3 or reduce the shielding of the third scan line 13-3 to the functional display region R1. In other words, in the third scan line 13-3, the portions extending along the first direction D1 and the portions extending along the second direction D2 belong to the same conductive layer (e.g., the conductive layer 17 in FIG. 1B).

In FIG. 1A, three types of lines are shown by solid lines with different thicknesses for facilitating identification of the layers to which the different lines belong instead of representing the widths of different lines. For example, the film layer to which the thick solid lines (e.g., the first portions P1) of the scan lines 13 belong may be the conductive layer 17 in FIG. 1B, and the film layer to which the thin solid lines (e.g., the second portions P2) of the scan lines 13 belong may be a conductive layer (not shown in FIG. 1B) disposed on the dielectric layer 18 and located between the dielectric layer 18 and the dielectric layer 19 in FIG. 1B, but not limited thereto. In addition, the film layer to which extremely thin solid lines (e.g., the first line W1, the second line W2, the third line W3, and the fourth line W4) connected between the light-emitting elements 11 and the pixel circuits 12 belong may be a conductive layer 25 in FIG. 1B, but not limited thereto.

FIG. 1B is a schematic cross-sectional view of section line I-I′ in FIG. 1A. With reference to FIG. 1B, the display device 1 may also include other elements or film layers depending on different requirements. For example, the display device 1 may also include a buffer layer 14. The buffer layer 14 is disposed on the substrate 10. The material of the buffer layer 14 may include inorganic materials, for example but not limited to, silicon oxide, silicon nitride, or a combination thereof.

The display device 1 may also include a semiconductive layer 15. The semiconductive layer 15 is disposed on the buffer layer 14. The material of the semiconductive layer 15 may include oxide semiconductor materials, for example but not limited to, an indium gallium zinc oxide (IGZO). In other embodiments, the material of the semiconductive layer 15 may include amorphous silicon, polysilicon, or metal oxide. For example, the semiconductive layer 15 is a patterned semiconductive layer and may include a plurality of semiconductor patterns 15P. The semiconductor patterns 15P may include a channel region CH, a source region SR, and a drain region DR. The channel region CH is located between the source region SR and the drain region DR.

The display device 1 may also include a dielectric layer 16. The dielectric layer 16 is disposed on the semiconductive layer 15 and the buffer layer 14. The material of the dielectric layer 16 may include inorganic materials, for example but not limited to, silicon oxide or silicon nitride.

The display device 1 may also include a conductive layer 17. The conductive layer 17 is disposed on the dielectric layer 16. The material of the conductive layer 17 may include a metal or a metal stack, for example but not limited to, aluminum, molybdenum, or titanium/aluminum/titanium. The conductive layer 17 may be a patterned conductive layer, and the conductive layer 17 may include a plurality of gates GE, a plurality of scan lines 13 (see FIG. 1A), and other circuits (not shown), but not limited thereto. The gates GE respectively overlap the channel regions CH in the third direction D3, and the gates GE are respectively electrically connected to the scan lines 13. In FIG. 1A, each pixel circuit 12 includes one gate GE, for example. In FIG. 1A, each scan line 13 is electrically connected to a plurality of pixel circuits 12. In the design that the RC loadings of different scan lines 13 are controlled by modulating the thicknesses of the scan lines 13, the gates GE electrically connected to the same scan line 13 and this electrically connected scan line 13 may have the same thickness.

The display device 1 may also include a dielectric layer 18. The dielectric layer 18 is disposed on the dielectric layer 16 and the conductive layer 17. Reference may be made to the material of the dielectric layer 16 for the material of the dielectric layer 18, which will not be repeatedly described here.

Although not shown in FIG. 1B, the display device 1 may also include a conductive layer disposed on the dielectric layer 18. Reference may be made to the material of the conductive layer 17 for the material of the conductive layer, which will not be repeatedly described here. The conductive layer may be a patterned conductive layer, and the conductive layer may include the portions (e.g., the second portions P2) extending in the first direction D1 of the scan lines 13 of FIG. 1A and other circuits (not shown), but not limited thereto.

The display device 1 may also include a dielectric layer 19. The dielectric layer 19 is disposed on the dielectric layer 18 and the conductive layer not shown. Reference may be made to the material of the dielectric layer 16 for the material of the dielectric layer 19, which will not be repeatedly described here.

The display device 1 may also include a conductive layer 20. The conductive layer 20 is disposed on the dielectric layer 19. Reference may be made to the material of the conductive layer 17 for the material of the conductive layer 20, which will not be repeatedly described here. The conductive layer 20 may be a patterned conductive layer, and the conductive layer may include a plurality of sources SE, a plurality of drains DE, a plurality of data lines (not shown), and other circuits (not shown), but not limited thereto. The sources SE are respectively electrically connected to the data lines, and each source SE may penetrate the dielectric layer 19, the dielectric layer 18, and the dielectric layer 16 to be electrically connected to the corresponding source region SR. Each drain DE may penetrate the dielectric layer 19, the dielectric layer 18, and the dielectric layer 16 to be electrically connected to the corresponding drain region DR. In FIG. 1A, each pixel circuit 12 includes one gate GE, one semiconductor pattern 15P, one drain DE, and one source SE, for example but not limited thereto.

The display device 1 may also include a dielectric layer 21. The dielectric layer 21 is disposed on the dielectric layer 19 and the conductive layer 20. Reference may be made to the material of the dielectric layer 16 for the material of the dielectric layer 21, which will not be repeatedly described here.

The display device 1 may also include a conductive layer 22. The conductive layer 22 is disposed on the dielectric layer 21. Reference may be made to the material of the conductive layer 17 for the material of the conductive layer 22, which will not be repeatedly described here. The conductive layer 22 may be a patterned conductive layer, and the conductive layer 22 may include a plurality of circuits CK, the lines (e.g., the first line W1, the second line W2, the third line W3, and the fourth line W4) connected between the light-emitting elements 11 and the pixel circuits 12 in FIG. 1A, and other circuits (not shown), but not limited thereto. Each circuit CK may penetrate the dielectric layer 21 to be electrically connected to the corresponding drain DE. Although not shown in FIG. 1B, the lines (e.g., the first line W1, the second line W2, the third line W3, and the fourth line W4) may penetrate the dielectric layer 21 to be electrically connected to the corresponding drain DE.

The display device 1 may also include a dielectric layer 23. The dielectric layer 23 is disposed on the dielectric layer 21 and the conductive layer 22. Reference may be made to the material of the dielectric layer 16 for the material of the dielectric layer 23, which will not be repeatedly described here.

Although not shown in FIG. 1B, the display device 1 may optionally include a conductive layer disposed on the dielectric layer 23. The material of the conductive layer may include a transparent conductive material. Alternatively, reference may be made to the material of the conductive layer 17, which will not be repeatedly described here. The transparent conductive material may include indium tin oxide (ITO), indium zinc oxide (IZO), or indium gallium zinc oxide (IGZO), but not limited thereto. The conductive layer may be a patterned conductive layer, and the conductive layer may include a plurality of portions (if any) extending in the second direction D2 of the data lines (not shown) and other circuits (not shown), but not limited thereto.

The display device 1 may also include a dielectric layer 24. The dielectric layer 24 is disposed on the dielectric layer 23 and the conductive layer not shown. Reference may be made to the material of the dielectric layer 16 for the material of the dielectric layer 24, which will not be repeatedly described here.

The display device 1 may also include a conductive layer 25. The conductive layer 25 is disposed on the dielectric layer 24. Reference may be made to the material of the conductive layer 17 for the material of the conductive layer 25, which will not be repeatedly described here. The conductive layer 25 may be a patterned conductive layer, and the conductive layer 25 may include a plurality of bottom electrodes BE of the light-emitting elements 11 in FIG. 1A and other circuits (not shown), but not limited thereto. Each bottom electrode BE may penetrate the dielectric layer 24 and the dielectric layer 23 to be electrically connected to the corresponding circuit CK.

The display device 1 may also include a spacer layer 26. The spacer layer 26 is disposed on the dielectric layer 24 and the conductive layer 25. The material of the spacer layer 26 may include black resin, white resin, or gray resin, but not limited thereto. The spacer layer 26 may include a plurality of openings A. Each opening A exposes one corresponding bottom electrode BE.

The display device 1 may also include a light-emitting layer 27. The light-emitting layer 27 may be a patterned light-emitting layer, and the light-emitting layer 27 may include a plurality of light-emitting patterns 27P. Each light-emitting pattern 27P is disposed in one corresponding opening A.

Although not shown in FIG. 1B, the display device 1 may also include a patterned conductive layer disposed on the light-emitting layer 27. The patterned conductive layer may include a plurality of top electrodes. Each top electrode is disposed in one corresponding opening A and covers the corresponding light-emitting pattern 27P. Each light-emitting element 11 in FIG. 1A includes one bottom electrode BE, one light-emitting pattern 27P, and one top electrode (not shown), for example but not limited thereto.

With reference to FIG. 2, the main differences between a display device 1A and the display device 1 of FIG. 1A are described below. In the display device 1A, the width W13-1 of the first scan line 13-1 is designed to be greater than the width W13-2 of the second scan line 13-2, and the width W13-2 of the second scan line 13-2 is designed to be equal to the width W13-3 of the third scan line 13-3. Accordingly, the RC loadings of the scan lines 13 electrically connected to different numbers of pixel circuits 12 approach the same loading.

According to some embodiments, although not shown in FIG. 2, the relatively wide scan lines 13 (e.g., the top two and bottom two scan lines 13 in FIG. 2) may be thinned (e.g., to be as wide as the middle four scan lines 13 of FIG. 2) at the overlaps with the semiconductor patterns 15P (see FIG. 1B), to maintain the same device properties (e.g., maintain the same ratio of the channel width to the channel length) for the pixel circuits 12 electrically connected to the scan lines 13 with different widths, but not limited thereto.

Although FIG. 2 shows two widths of the scan lines 13 in the display device 1A, but not limited thereto. For example, when different scan lines 13 are electrically connected to two or more numbers of pixel circuits 12, the scan lines 13 in the display device 1A may have two or more widths.

With reference to FIG. 3, the main differences between a display device 1B and the display device 1 of FIG. 1A are described below. In the display device 1B, the first scan line 13-1 is designed to be less than the second scan line 13-2 in length, and the second scan line 13-2 is designed to be equal to the third scan line 13-3 in length. Accordingly, the RC loadings of the scan lines 13 electrically connected to different numbers of pixel circuits 12 approach the same loading.

In FIG. 3, the middle portions of the third scan lines 13-3 adopt a winding design in the form of a square wave to increase the length. Nonetheless, the form of the winding design is not limited to the square wave form. For example, the winding design may also include a triangle wave, a sine wave, winding designs in other shapes, or a combination thereof.

FIG. 4A is a schematic enlarged view of a region of a display device 1C where the fifth light-emitting element 11-5, the fifth pixel circuit 12-5, the third light-emitting element 11-3, the third pixel circuit 12-3, the fourth line W4, and the second line W2 are located. FIG. 4B is a schematic cross-sectional view of section line II-II′ in FIG. 4A.

With reference to FIG. 4A and FIG. 4B, in the display device 1C, each of the second line W2 and the fourth line W4 includes a first segment SC1 disposed on the functional display region R1 and a second segment SC2 disposed on the general display region R2 (e.g., the second display region R22), and the first segment SC1 is greater in transparency than the second segment SC2. Specifically, the first segment SC1 and the second segment SC2 belong to different conductive layers. Taking FIG. 4B as an example, the first segment SC1 may belong to a conductive layer 28 disposed on the dielectric layer 23, and the second segment SC2 may belong to the conductive layer 22 disposed on the dielectric layer 21. The conductive layer 28 may be a transparent conductive layer, and the conductive layer 22 may be a metal conductive layer, such that the first segment SC1 is greater in transparency than the second segment SC2. The transparency is transparency relative to visible light (e.g., light with wavelengths within the range of 400 nm to 700 nm).

In the line, the portion (e.g., the first segment SC1) disposed on the functional display region R1 is made of a transparent conductive material, which helps reduce the light-shielding degree of the line to the functional display region R1, improving the transparency of the functional display region R1.

In FIG. 4A, although the second line W2 and the fourth line W4 are taken as an example for description, other lines (e.g., the first line W1, the third line W3, or other lines not shown) extending into the functional display region R1 in FIG. 1A, FIG. 2, or FIG. 3 may also adopt the above design to improve the transparency of the functional display region R1. Taking the first line W1 of FIG. 1A as an example, the first line W1 may include a first segment (not shown in FIG. 1A) disposed on the functional display region R1 and a second segment (not shown in FIG. 1A) disposed on the first display region R21, and the first segment may be greater in transparency than the second segment.

FIG. 5A is a schematic enlarged view of a region of a display device 1D where the fifth light-emitting element 11-5, the fifth pixel circuit 12-5, the third light-emitting element 11-3, the third pixel circuit 12-3, the fourth line W4, and the second line W2 are located. FIG. 5B is a schematic cross-sectional view of section line III-III′ in FIG. 5A.

With reference to FIG. 5A and FIG. 5B, in the display device 1D, two adjacent lines may belong to different conductive layers. For example, the second line W2 may belong to the conductive layer 22 disposed on the dielectric layer 21, and the fourth line W4 may belong to the conductive layer 28 disposed on the dielectric layer 23.

Through the design of two adjacent lines belonging to different conductive layers, it is possible to reduce the difficulty in manufacturing or reduce the probability of two lines being connected together (short circuits) due to process variations or errors.

Under the architecture of FIG. 5A and FIG. 5B, the transparency of the conductive layer 22 and the conductive layer 28 is not limited. In other words, the material of each of the conductive layer 22 and the conductive layer 28 may include a transparent conductive material, a metal, or a metal stack.

In FIG. 5A, although the second line W2 and the fourth line W4 are taken as an example for description, any two adjacent lines (including the first line W1 and the third line W3) in FIG. 1A, FIG. 2, or FIG. 3 may also adopt the above design.

FIG. 6A is a schematic enlarged view of a region of a display device 1E where the fifth light-emitting element 11-5, the fifth pixel circuit 12-5, the third light-emitting element 11-3, the third pixel circuit 12-3, the fourth line W4, and the second line W2 are located. FIG. 6B is a schematic cross-sectional view of section line IV-IV′ in FIG. 6A.

With reference to FIG. 6A and FIG. 6B, in the display device 1E, two adjacent lines may belong to different conductive layers and may overlap in the third direction D3. For example, the second line W2 may belong to the conductive layer 22 disposed on the dielectric layer 21, and the fourth line W4 may belong to the conductive layer 28 disposed on the dielectric layer 23. In addition, the second line W2 and the fourth line W4 may overlap in the third direction D3.

Through the design of two adjacent lines belonging to different conductive layers and overlapping in the third direction D3, it helps reduce a distance DT between the pixel circuits 12 in two horizontal rows, satisfying the design requirements for a high resolution or a small size.

With reference to FIG. 7, a display device 1F may also include a chip 29, a chip 30, a plurality of data lines 31, and a plurality of data lines 32, but not limited thereto. Illustration of the light-emitting elements, the pixel circuits, the scan lines, the lines, and the like are omitted from FIG. 7 for clarity of the drawing.

The chip 29 and the chip 30 are data drivers, for example. According to some embodiments, the chip 29 and the chip 30 may be respectively disposed at opposite sides of the display device 1F, for example but not limited to, the upper and lower sides. The data lines 31 and the data lines 32 extend in the first direction D1 and are arranged in the second direction D2. The data lines 31 electrically connect the chip 29 with the pixel circuits (not shown in FIG. 7) electrically connected to the light-emitting elements (not shown in FIG. 7) disposed on the general display region R2. The data lines 32 electrically connect the chip 30 with the pixel circuits (not shown in FIG. 7) electrically connected to the light-emitting elements (not shown in FIG. 7) disposed on the functional display region R1. Taking FIG. 1A as an example, the chip 30 (the data driver) may be electrically connected to the first pixel circuit 12-1, and the first pixel circuit 12-1 is disposed between the data driver (the chip 30) and the functional display region R1, for example. According to some embodiments, the data lines 32 may be made of a transparent conductive layer to reduce the light-shielding degree of the data lines 32 to the functional display region R1. Alternatively, the data lines 32 may also adopt the design of the transparent line accompanied with the metal line in FIG. 4A to reduce the light-shielding degree of the data lines 32 to the functional display region R1.

According to other embodiments, although not so shown, the chip 30 and the data lines 32 may be omitted, and the data lines 31 may also electrically connect the chip 29 with the pixel circuits (not shown in FIG. 7) electrically connected to the light-emitting elements (not shown in FIG. 7) disposed on the general display region R2.

According to some embodiments, the general display region R2 may be divided into a buffer region R23 surrounding the functional display region R1 and a display region R24 located between the buffer region R23 and the chip 29. According to some embodiments, the light-emitting elements (not shown in FIG. 7) on the functional display region R1 may be less than or equal to the light-emitting elements on the buffer region R23 in distribution density. In addition, the light-emitting elements on the buffer region R23 may be less than or equal to the light-emitting elements on the display region R24 in distribution density.

FIG. 7 schematically shows one functional display region R1, one buffer region R23, and one display region R24. The buffer region R23 surrounds the functional display region R1, and the buffer region R23 and the display region R24 have the same width in the second direction D2. Nonetheless, parameters such as the number, size, shape, or relative arrangement relationship of each of the regions may be changed depending on the requirements. For example, the number of functional display region R1 may be greater than 1. The buffer region R23 may be less than the display region R24 in width in the second direction D2. In addition, the display region R24 may be disposed at three sides of the buffer region R23 or may surround the buffer region R23.

With reference to FIG. 8, the main differences between a display device 1G and the display device 1 of FIG. 1A are described below. In FIG. 8, the scan lines 13 and the lines (e.g., the first line W1, the second line W2, the third line W3, and the fourth line W4) connected between the light-emitting elements 11 and the pixel circuits 12 of FIG. 1A are not shown for clarity of the drawing.

In the display device 1G, the number of light-emitting elements 11 disposed on the functional display region R1 is greater than the number of light-emitting elements 11 disposed on the functional display region R1 in FIG. 1A, and the light-emitting elements 11 may be respectively electrically connected to the corresponding pixel circuits 12 disposed on the general display region R2 through the lines (not shown in FIG. 8) connected between the light-emitting elements 11 and the pixel circuits 12.

According to some embodiments, the pixel circuits 12 electrically connected to the light-emitting elements 11 disposed on the functional display region R1 and the general display region R2 and arranged in the first direction D1 may share the same data line 31. Taking FIG. 8 as an example, the first light-emitting element 11-1, the fourth light-emitting element 11-4, a sixth light-emitting element 11-6, and a seventh light-emitting element 11-7 are disposed on the functional display region R1 or the general display region R2 and are arranged in the first direction D1. In addition, the first pixel circuit 12-1, the fourth pixel circuit 12-4, a sixth pixel circuit 12-6, and a seventh pixel circuit 12-7 respectively electrically connected to the first light-emitting element 11-1, the fourth light-emitting element 11-4, the sixth light-emitting element 11-6, and the seventh light-emitting element 11-7 are disposed on the general display region R2 and are arranged in the first direction D1, for example. A first data line 31-1 among the data lines 31 is electrically connected to the first pixel circuit 12-1, the fourth pixel circuit 12-4, the sixth pixel circuit 12-6, and the seventh pixel circuit 12-7.

In FIG. 8, the first data line 31-1 adopts a winding design. In other words, the first data line 31-1 changes the extension direction of the line under the architecture of the same conductive layer (e.g., the conductive layer 20 in FIG. 1B) to reduce the shielding of the first data line 31-1 to the functional display region R1. In other words, the portions extending along the first direction D1 and the portions extending along the second direction D2 of the first data line 31-1 belong to the same conductive layer (e.g., the conductive layer 20 in FIG. 1B).

In FIG. 8, a second data line 31-2 adopts an adapter cable design to decrease the shielding of the second data line 31-2 to the functional display region R1. To be specific, the second data line 31-2 includes three third portions P3 (represented by thick solid lines) and two fourth portions P4 (represented by thin solid lines). The three third portions P3 each extend in the first direction D1, and the two fourth portions P4 each extend in the second direction D2. From a top view of the display device 1G, the three third portions P3 are respectively disposed at the upper, lower, and left sides of the functional display region R1, and the two fourth portions P4 are respectively disposed at the upper left side and the lower left side of the functional display region R1. The fourth portion P4 located at the upper left side of the functional display region R1 electrically connects the third portion P3 located at the left side of the functional display region R1 with the third portion P3 located at the upper side of the functional display region R1, and the fourth portion P4 located at the lower left side of the functional display region R1 electrically connects the third portion P3 located at the left side of the functional display region R1 with the third portion P3 located at the lower side of the functional display region R1. The conductive layer (e.g., the conductive layer 20 in FIG. 1B) to which the three third portions P3 belong is different from the conductive layer (e.g., the conductive layer 28 in the FIG. 4B) to which the two fourth portions P4 belong, and the fourth portions P4 are electrically connected to the corresponding third portions P3 through conductive vias (not shown) penetrating the dielectric layer 23 and the dielectric layer 21, for example.

With reference to FIG. 9, the main differences between a display device 1H and the display device 1G of FIG. 8 are described below. In the display device 1H, the number of light-emitting elements 11 disposed on the functional display region R1 is greater than the number of light-emitting elements 11 disposed on the functional display region R1 in FIG. 8, and the light-emitting elements 11 may be respectively electrically connected to the corresponding pixel circuits 12 disposed on the general display region R2 through the lines (not shown in FIG. 9) connected between the light-emitting elements 11 and the pixel circuits 12.

In addition, in FIG. 9, the first data line 31-1 crosses the functional display region R1. To be specific, the first data line 31-1 may include a portion P5 crossing the functional display region R1 and a portion P6 winding to pass by the functional display region R1. According to some embodiments, the conductive layer (e.g., the conductive layer 20 in FIG. 1B) to which the portion P5 belongs is different from the conductive layer (e.g., the conductive layer 28 in FIG. 4B) to which the portion P6 belongs, and the portion P6 is electrically connected to the portion P5 through conductive vias (not shown) penetrating the dielectric layer 23 and the dielectric layer 21, for example. The RC loadings of the data lines 31 can be reduced through the design of dual signal transmission paths (including two signal transmission paths of the portion P5 and the portion P6) of a single data line.

According to another embodiment, although not shown, the portion P5 may adopt the design of the transparent line (the segment on the functional display region R1) accompanied with the metal line (the segment on the general display region R2) in FIG. 4A to reduce the light-shielding degree of the data lines 31 to the functional display region R1.

With reference to FIG. 10, the main differences between a display device 1I and the display device 1G of FIG. 8 are described below. In FIG. 10, the scan lines 13 and the data lines 31 are not shown for clarity of the drawing.

In the display device 1I, the number of light-emitting elements 11 disposed on the functional display region R1 is less than the number of light-emitting elements 11 disposed on the general display region R2 to improve the transparency of the functional display region R1, but not limited thereto. According to other embodiments, the number of light-emitting elements 11 disposed on the functional display region R1 may be equal to the number of light-emitting elements 11 disposed on the general display region R2.

In the display device 1I, the pixel circuits 12 electrically connected to some of the light-emitting elements 11 (e.g., a light-emitting element 11A) disposed on the general display region R2 are replaced with pixel circuits 12′ with a smaller top-view area, and the space saved by the replacement is taken to accommodate a plurality of pixel circuits 12″ electrically connected to the light-emitting elements 11 disposed on the functional display region R1. Taking FIG. 10 as an example, the pixel circuit 12′ and the pixel circuit 12″ overlap the light-emitting element 11A in the third direction D3, for example. In addition, the pixel circuit 12′ and the pixel circuit 12″ may be disposed at opposite sides of the light-emitting element 11A. Under this architecture, the pixel circuit 12′ and the pixel circuit 12″ have a top-view area smaller than the pixel circuit 12, and the pixel circuit 12′ and the pixel circuit 12″ may have the same or different top-view areas. FIG. 10 schematically shows that the pixel circuit 12′ and the pixel circuit 12″ have the same top-down area, but the disclosure is not limited thereto.

With reference to FIG. 11A to FIG. 11C, for example, a display device 1J is a mobile phone that may display an image at a side surface. The display device 1J may also include a first-side display region RS1, a second-side display region RS2, a third-side display region RS3, and a fourth-side display region RS4, for example but not limited thereto. Although not shown, each of the first-side display region RS1 to the fourth-side display region RS4 may include the light-emitting elements, the pixel circuits, the scan lines, and the data lines.

FIG. 11C schematically shows a region (including part of the general display region R2 and part of the first-side display region RS1) adjacent to the functional display region R1 in the display device 1J. As shown in FIG. 11C, the display device 1J may include a plurality of red light-emitting elements 11R, a plurality of green light-emitting elements 11G, and a plurality of blue light-emitting elements 11B, but not limited thereto. In addition, the display device 1J may also include a plurality of red pixel circuits 12R, a plurality of green pixel circuits 12G, and a plurality of blue pixel circuits 12B, but not limited thereto. Each red pixel circuit 12R is electrically connected to one corresponding red light-emitting element 11R. Each green pixel circuit 12G is electrically connected with one corresponding green light-emitting element 11G. Each blue pixel circuit 12B is electrically connected to one corresponding blue light-emitting element 11B.

The light-emitting elements (e.g., the red light-emitting element 11R, the green light-emitting element 11G, or the blue light-emitting element 11B) disposed on the general display region R2, on the first-side display region RS1, on the second-side display region RS2, on the third-side display region RS3, or on the fourth-side display region RS4 and the pixel circuits (e.g., the red pixel circuit 12R, the green pixel circuit 12G, or the blue pixel circuit 12B) electrically connected to the light-emitting elements may be disposed overlapping in the third direction D3.

Comparatively, the pixel circuits (e.g., the red pixel circuit 12R′, the green pixel circuit 12G′, or the blue pixel circuit 12B′) electrically connected to the light-emitting elements (e.g., the red light-emitting element 11R, the green light-emitting element 11G, or the blue light-emitting element 11B) disposed on the functional display region R1 may be disposed on the first-side display region RS1 to be electrically connected to the corresponding light-emitting elements through lines (not shown).

According to other embodiments, although not shown, FIG. 11C may also adopt the design of FIG. 10, that is, to satisfy the design requirements for a high resolution or a small size by reducing the top-view area of some pixel circuits.

With reference to FIG. 12, the main differences between a display device 1K and the display device 1 of FIG. 1A are described below. In FIG. 12, the scan lines 13 and the data lines 31 are not shown for clarity of the drawing.

In the display device 1K, the substrate 10 also includes a functional display region R1′. The functional display region R1′ and the functional display region R1 are separated from each other and arranged in the second direction D2. In addition, the number of light-emitting elements 11 disposed on the functional display region R1′ is less than the number of light-emitting elements 11 disposed on the functional display region R1 to improve the transparency of the functional display region R1′, for example but not limited thereto. According to other embodiments, although not shown, the number of light-emitting elements 11 disposed on the functional display region R1′ may be equal to the number of light-emitting elements 11 disposed on the functional display region R1.

In addition to providing a display function, the functional display region R1 and the functional display region R1′ may also provide additional functions. For example, a camera module (not shown) in the display device 1K may be disposed below the functional display region R1 to provide functions such as image capturing or video capturing, and a non-visible light (e.g., infrared light) sensing module in the display device 1K may be disposed below the functional display region R1′ to provide a function of biometric identification (e.g., fingerprint identification), for example but not limited thereto.

In summary of the foregoing, in the embodiments of the disclosure, by disposing at least some pixel circuits outside the functional display region, it helps improve the transparency of the functional display region.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

Although the embodiments and the advantages thereof have been disclosed as above, it should be understood that, a person skilled in the art may make variations, replacements, and modifications, and features among the embodiments may be arbitrarily mixed and replaced with each other into other newly formed embodiments without departing from the spirit and scope of the disclosure. In addition, the protection scope of the disclosure is not limited to the process, machine, manufacture, composition of matters, device, method, or step in the specifically described embodiments in the description. A person skilled in the art can understand from the content of the disclosure that the existing or to-be-developed process, machine, manufacture, composition of matters, device, method, or step may be used according to the disclosure as long as the substantially same function can be implemented or the substantially same result can be obtained in the embodiments described herein. Therefore, the protection scope of the disclosure includes the above-mentioned process, machine, manufacture, composition of matters, device, method, or step. Moreover, each claim forms an individual embodiment, and the protection scope of the disclosure also includes a combination of each of the claims and embodiments. The protection scope of the disclosure should be subject to the appended claims.

What is claimed is:

1. A display device comprising:
a substrate comprising a functional display region and a first display region adjacent to the functional display region in a first direction;
a first light-emitting element disposed on the functional display region;
a first pixel circuit disposed on the first display region and electrically connected to the first light-emitting element;
a second light-emitting element disposed on the first display region;
a second pixel circuit disposed on the first display region and electrically connected to the second light-emitting element; and
a first scan line electrically connected to the first pixel circuit and the second pixel circuit and extending in a second direction perpendicular to the first direction.

2. The display device according to claim 1, wherein the first pixel circuit and the second pixel circuit are arranged in the second direction.

3. The display device according to claim 1, wherein the substrate further comprises a second display region adjacent to the functional display region in the second direction, and the display device further comprises:
a third light-emitting element disposed on the functional display region; and
a third pixel circuit disposed on the second display region and electrically connected to the third light-emitting element.

4. The display device according to claim 3, further comprising:
a second scan line electrically connected to the third pixel circuit, wherein a number of pixel circuits electrically connected to the first scan line is greater than a number of pixel circuits electrically connected to the second scan line.

5. The display device according to claim 4, wherein the first scan line is greater in width than the second scan line.

6. The display device according to claim 4, wherein the first scan line is greater in thickness than the second scan line.

7. The display device according to claim 4, wherein the first scan line is less in length than the second scan line.

8. The display device according to claim 3, wherein the first pixel circuit is electrically connected to the first light-emitting element through a first line, the third pixel circuit is electrically connected to the third light-emitting element through a second line, the first line extends in the first direction, and the second line extends in the second direction.

9. The display device according to claim 8, wherein at least one of the first line and the second line comprises a transparent conductive material.

10. The display device according to claim 8, wherein the first line comprises a first segment disposed on the functional display region and a second segment disposed on the first display region, and the first segment is greater in transparency than the second segment.

11. The display device according to claim 1, further comprising:
a fourth light-emitting element disposed on the functional display region, the fourth light-emitting element and the first light-emitting element being arranged in the first direction;
a fourth pixel circuit disposed on the first display region and electrically connected to the fourth light-emitting element; and
a first data line electrically connected to the first pixel circuit and the fourth pixel circuit.

12. The display device according to claim 11, wherein the first data line crosses the functional display region.

13. The display device according to claim 1, further comprising:
a data driver electrically connected to the first pixel circuit, wherein the first pixel circuit is disposed between the data driver and the functional display region.

14. An electronic device comprising:
the display device according to claim 1; and
a sensing device overlapping the functional display region in a top view of the display device.

15. The electronic device according to claim 14, wherein the sensing device is a camera module.
